(19) United States
(12) Patent Application Publication
(10) Pub. No.: US 2026/0156805 A1
(43) Pub. Date: Jun. 4, 2026

(54) SEMICONDUCTOR MEMORY DEVICE

(71) Applicant: SAMSUNG ELECTRONICS CO., LTD., Suwon-si (KR)

(72) Inventors: Seung Min LEE, Suwon-si (KR); Jong Ho KIM, Suwon-si (KR); Hyun Jae LEE, Suwon-si (KR); Sung Won YOO, Suwon-si (KR)

(21) Appl. No.: 19/253,647

(22) Filed: Jun. 27, 2025

(30) Foreign Application Priority Data
Dec. 4, 2024 (KR) 10-2024-0178643

(51) Int. Cl. H10B 12/00; G11C 5/06; H10D 30/60

(52) U.S. Cl. CPC H10B 12/33; G11C 5/063; H10B 12/05; H10B 12/482; H10B 12/485; H10B 12/488; H10D 30/611

(57) ABSTRACT

The present disclosure relates to a semiconductor memory device with improved integration density and electrical characteristics. An example semiconductor memory device includes a contact pattern, a data storage pattern connected with a first surface of the contact pattern, a channel pattern connected with a second surface of the contact pattern, a bitline disposed on the channel pattern, connected with the channel pattern, and including an extension portion and a protruding portion, where the extension portion extends in a second direction and includes a third surface and a fourth surface opposite to each other in the first direction, and the protruding portion protrudes from the third surface toward the contact pattern, a metal structure surrounding at least portions of sidewalls of the protruding portion of the bitline, and a wordline disposed on the channel pattern and extending in a third direction.

### CROSS-REFERENCE TO RELATED APPLICATION

This application claims priority from Korean Patent Application No. 10-2024-0178643 filed on December 4, 2024, in the Korean Intellectual Property Office, and all the benefits accruing therefrom under 35 U.S.C. 119, the contents of which in its entirety are herein incorporated by reference.

### BACKGROUND

Increasing the integration density of semiconductor memory devices is desired to meet consumer demands for excellent performance and low cost. For semiconductor memory devices, integration density is relevant to determining product cost, and thus, a particularly high integration density is desired.

For two-dimensional (2D) or planar semiconductor memory devices, integration density primarily depends on the area occupied by a unit memory cell and is therefore significantly affected by the level of fine patterning technology. However, since miniaturizing patterns requires ultra-high-cost equipment, the integration density of 2D semiconductor memory devices, although increasing, remains limited.

### SUMMARY

Semiconductor memory devices including vertical channel transistors, where channels extend in a vertical direction, have been proposed. The present disclosure relates to a semiconductor memory device with improved integration density and electrical characteristics.

The objectives of the present disclosure are not limited to those mentioned above, and other objectives not explicitly stated will be clearly understood by those skilled in the art based on the following description.

In some implementations, a semiconductor memory device comprises a contact pattern including a first surface and a second surface opposite to each other in a first direction, a data storage pattern connected to the first surface of the contact pattern, a channel pattern connected to the second surface of the contact pattern, a bitline disposed on the channel pattern, connected to the channel pattern, and including an extension portion and a protruding portion, wherein the extension portion of the bitline extends in a second direction and includes a third surface and a fourth surface opposite to each other in the first direction, and the protruding portion of the bitline protrudes from the third surface of the extension portion of the bitline toward the contact pattern a metal structure surrounding at least portions of sidewalls of the protruding portion of the bitline, and a wordline disposed on the channel pattern and extending in a third direction

In some implementations, a semiconductor memory device comprises a contact pattern including a first surface and a second surface opposite to each other in a first direction, a data storage pattern connected to the first surface of the contact pattern, a channel pattern connected to the second surface of the contact pattern, a bitline disposed on the channel pattern and connected to the channel pattern, a metal structure disposed between the bitline and the channel pattern and including an upper surface and a bottom surface opposite to each other in the first direction, and inner sidewalls and outer sidewalls connecting the upper surface and the bottom surface, and a wordline disposed on the channel pattern and extending in a second direction, wherein the inner sidewalls of the metal structure are in contact with the bitline.

In some implementations, a semiconductor memory device comprises a peripheral gate structure disposed on a substrate, a contact pattern disposed on the peripheral gate structure and including a first surface and a second surface opposite to each other in a first direction, a data storage pattern disposed between the peripheral gate structure and the contact pattern, and connected to the first surface of the contact pattern, a channel pattern connected to the second surface of the contact pattern, a bitline disposed on the channel pattern, connected to the channel pattern, and including an extension portion and a protruding portion, wherein the extension portion of the bitline extends in a second direction and includes a third surface and a fourth surface opposite to each other in the first direction, and the protruding portion of the bitline protrudes from the third surface of the extension portion of the bitline toward the contact pattern, a metal structure surrounding at least portions of sidewalls of the protruding portion of the bitline, a wordline disposed on the channel pattern and extending in a third direction, and a bitline contact liner disposed between the channel pattern and the metal structure, wherein the bitline contact liner includes a first portion extending along the third surface of the extension portion of the bitline and the sidewalls of the protruding portion of the bitline, a second portion extending along a boundary between the channel pattern and the metal structure, and a third portion extending along a bottom surface of the protruding portion of the bitline.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail illustrative implementations thereof with reference to the attached drawings.

FIG. 1 is a schematic layout view of an example of a semiconductor memory device.

FIG. 2 is a layout view of an example of a cell array region in FIG. 1.

FIG. 3 is an example cross-sectional view taken along lines A-A and B-B in FIG. 2.

FIG. 4 is an example cross-sectional view taken along lines C-C and D-D in FIG. 2.

FIG. 5 is an example enlarged view of portion P1 in FIG. 3.

FIG. 6 is an example enlarged view of portion Q in FIG. 5.

FIG. 7 is a perspective view illustrating an example of a metal structure.

FIG. 8 is an enlarged view of portion P1 (in FIG. 3) of an example of a semiconductor memory device.

FIG. 9 is an enlarged view of portion P1 (in FIG. 3) of an example of a semiconductor memory device.

FIG. 10 is a cross-sectional view, taken along lines A-A and B-B of FIG. 2, of an example of a semiconductor memory device.

FIG. 11 is an example enlarged view of portion P2 in FIG. 10.

FIG. 12 is a cross-sectional view, taken along lines A-A and B-B of FIG. 2, of an example of a semiconductor memory device.

FIG. 13 is an example enlarged view of portion P2 in FIG. 12.

FIGS. 14,15,16,17,18,19,20,21,22,23,24,25,26, and 27 illustrate intermediate steps of an example of a method of fabricating a semiconductor memory device.

### DETAILED DESCRIPTION

In this specification, although “first,” “second,” and similar terms are used to describe various elements or components, these elements or components are not limited by these terms. These terms are merely used to distinguish one element or component from another. Therefore, a first element or component described below may also be a second element or component within the technical scope of the present disclosure.

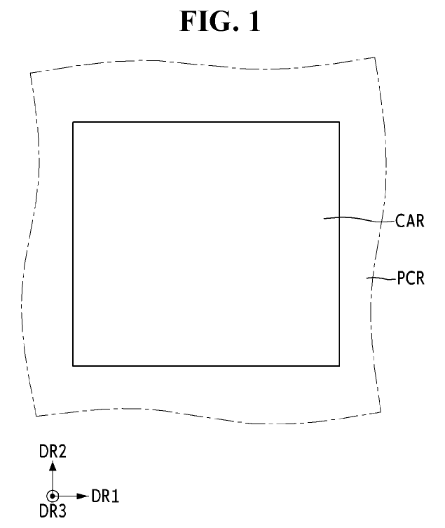

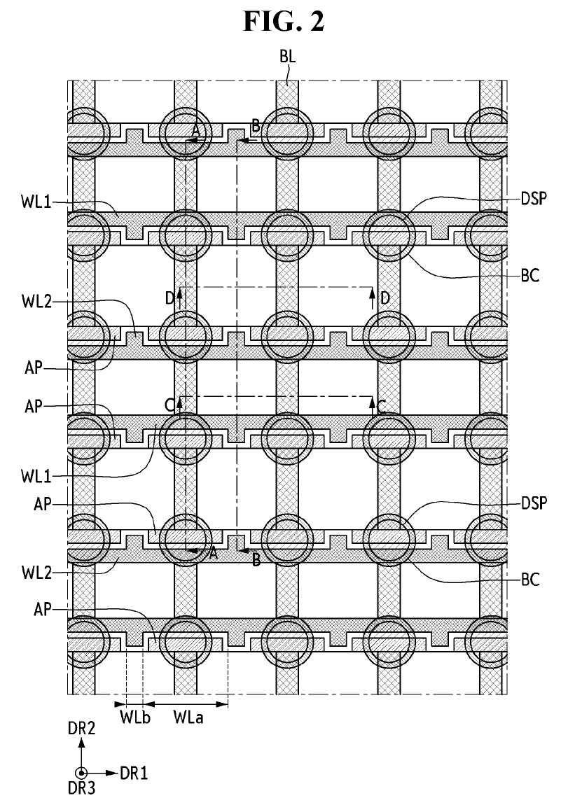

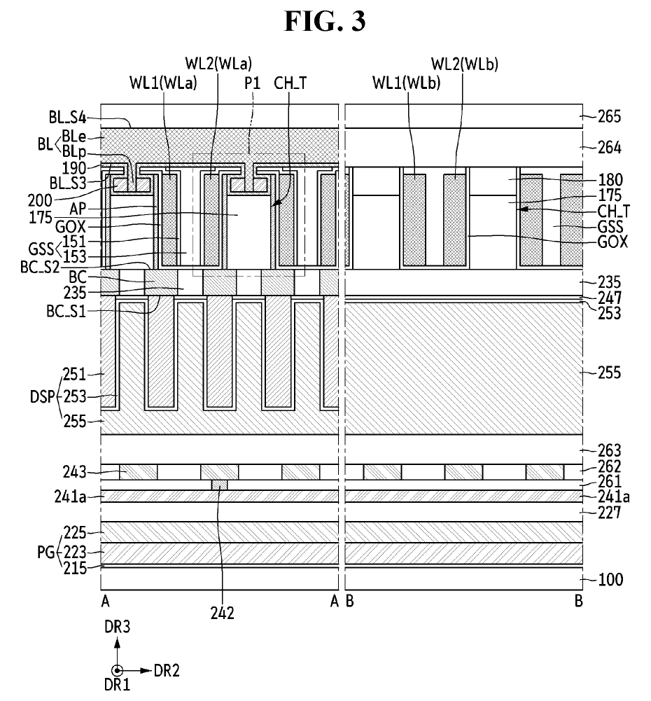

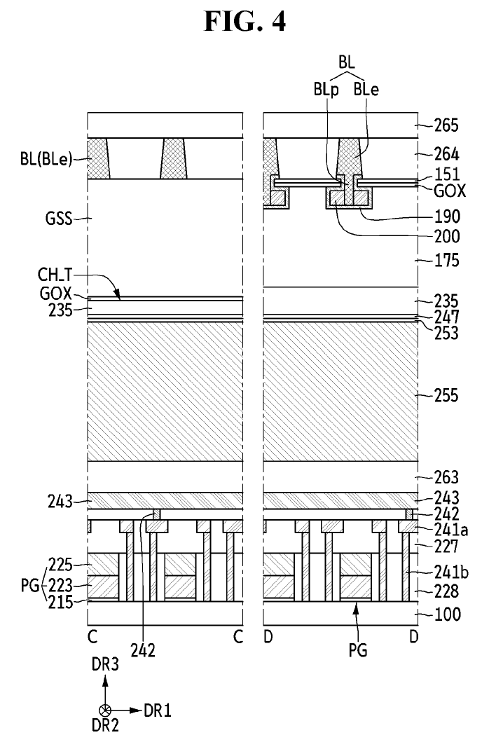

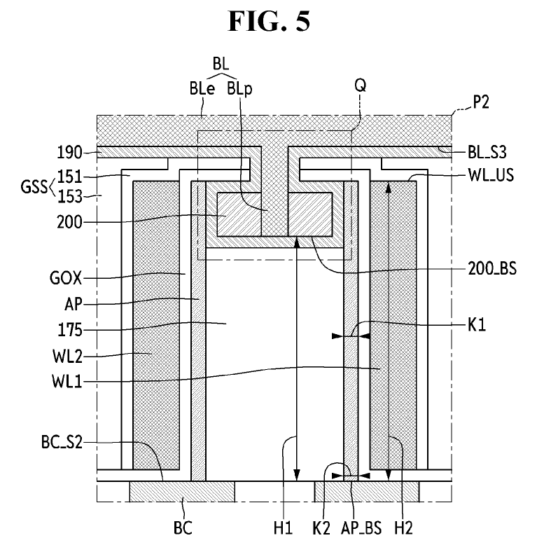

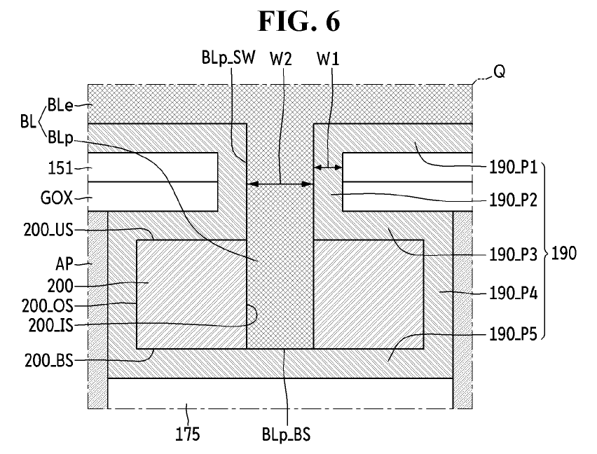

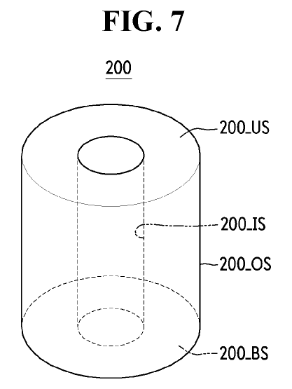

FIG. 1 is a schematic layout view of an example of a semiconductor memory device. FIG. 2 is a layout view of an example of a cell array region in FIG. 1. FIG. 3 is an example cross-sectional view taken along lines A-A and B-B in FIG. 2. FIG. 4 is an example cross-sectional view taken along lines C-C and D-D in FIG. 2. FIG. 5 is an example enlarged view of portion P1 in FIG. 3. FIG. 6 is an example enlarged view of portion Q in FIG. 5. FIG. 7 is a perspective view illustrating an example of a metal structure.

The semiconductor memory device may include memory cells including vertical channel transistors (VCTs).

Referring to FIGS. 1 through 7, the semiconductor memory device may include a peripheral gate structure PG, bitlines BL, wordlines (WL1 and WL2), channel patterns AP, contact patterns BC, data storage patterns DSP, metal structures 200, and a bitline contact liner 190.

A substrate 100 may include a cell array region CAR where the data storage patterns DSP are arranged, and a peripheral circuit region PCR defined around the cell array region CAR. The substrate 100 may be a silicon substrate, or may include other materials such as silicon-germanium, indium antimonide, lead telluride compound, indium arsenide, indium phosphide, gallium arsenide, or gallium antimonide, but is not limited thereto.

The peripheral gate structure PG may be disposed on the substrate 100. The substrate 100 may include the cell array region CAR and the peripheral circuit region PCR. The peripheral gate structure PG may be disposed across the cell array region CAR and the peripheral circuit region PCR. That is, part of the peripheral gate structure PG may be disposed in the cell array region CAR of the substrate 100, while the remaining part of the peripheral gate structure PG may be disposed in the peripheral circuit region PCR of the substrate 100.

The peripheral gate structure PG may be included in sensing transistors, transfer transistors, and driving transistors. The types of transistors disposed in the cell array region CAR and the peripheral circuit region PCR may vary depending on the design layout of the semiconductor memory device.

The peripheral gate structure PG may include a peripheral gate insulating film 215, a peripheral lower conductive pattern 223, and a peripheral upper conductive pattern 225. The peripheral gate insulating film 215 may include a silicon oxide film, a silicon oxynitride film, a high-k dielectric insulating film having a greater dielectric constant than a silicon oxide film, or a combination thereof. The high-k dielectric insulating film may include at least one of a metal oxide, a metal oxynitride, a metal silicon oxide, or a metal silicon oxynitride, but is not limited thereto.

The peripheral lower conductive pattern 223 and the peripheral upper conductive pattern 225 may each include a conductive material. For example, the peripheral lower conductive pattern 223 and the peripheral upper conductive pattern 225 may each include at least one of a doped semiconductor material, a conductive metal nitride, a conductive metal silicon nitride, a metal carbonitride, a conductive metal silicide, a conductive metal oxide, a two-dimensional (2D) material, a metal, or a metal alloy. The peripheral gate structure PG is illustrated as including multiple conductive patterns, but is not limited thereto.

In the semiconductor memory device, the 2D material may be a metallic material and/or a semiconductor material. The 2D material may include a 2D allotrope or a 2D compound, and may include at least one of graphene, molybdenum disulfide (MoS₂), molybdenum diselenide (MoSe₂), tungsten diselenide (WSe₂), or tungsten disulfide (WS₂), but is not limited thereto. That is, the aforementioned 2D materials are merely examples, and the present disclosure is not limited thereto.

A first peripheral lower insulating film 227 and a second peripheral lower insulating film 228 may be disposed on the substrate 100. The first peripheral lower insulating film 227 and the second peripheral lower insulating film 228 may each include an insulating material.

The second peripheral lower insulating film 228 is illustrated as being in contact with the sidewalls of the peripheral lower conductive pattern 223 and the peripheral upper conductive pattern 225, but is not limited thereto. The peripheral gate structure PG may include peripheral gate spacers disposed on the sidewalls of the peripheral lower conductive pattern 223 and the peripheral upper conductive pattern 225.

A peripheral wiring line 241a and a peripheral contact plug 241b may be disposed in the first peripheral lower insulating film 227 and the second peripheral lower insulating film 228. The peripheral contact plug 241b may be connected to a source/drain region disposed on at least one side of the peripheral gate structure PG. For example, the source/drain region may be a doped region in the substrate 100, but is not limited thereto. Although not illustrated, the peripheral contact plug 241b may be connected to the peripheral conductive lower and upper patterns 223 and 225 of the peripheral gate structure PG.

The peripheral wiring line 241a may be disposed on the peripheral contact plug 241b. The peripheral wiring line 241a is connected to the peripheral contact plug 241b. For example, the peripheral wiring line 241a may be the closest wiring line to the peripheral gate structure PG in a third direction DR3.

The peripheral wiring line 241a and the peripheral contact plug 241b are illustrated as being different films, but are not limited thereto. The boundary between the peripheral wiring line 241a and the peripheral contact plug 241b may not be distinguishable. The peripheral wiring line 241a and the peripheral contact plug 241b each include a conductive material.

A first peripheral upper insulating film 261 and a second peripheral upper insulating film 262 may be disposed on the peripheral wiring line 241a and the peripheral contact plug 241b. The first peripheral upper insulating film 261 and the second peripheral upper insulating film 262 may each include an insulating material.

A peripheral connection wiring 243 and a peripheral connection via 242 may be disposed on the peripheral wiring line 241a. The peripheral connection via 242 may be arranged in the first peripheral upper insulating film 261. The peripheral connection wiring 243 may be arranged in the second peripheral upper insulating film 262.

The peripheral connection wiring 243 and the peripheral connection via 242 may be connected to the peripheral wiring line 241a. The peripheral connection via 242 may connect the peripheral wiring line 241a and the peripheral connection wiring 243. The peripheral connection wiring 243 and the peripheral connection via 242 may each include a conductive material. The peripheral connection wiring 243 and the peripheral connection via 242 are illustrated as different films, but are not limited thereto. The boundary between the peripheral connection wiring 243 and the peripheral connection via 242 may not be distinguishable.

The peripheral wiring line 241a is illustrated as having a single peripheral connection wiring disposed at one metal level, but is not limited thereto. Contrary to what is illustrated, a plurality of peripheral connection wirings 243 disposed at different metal levels may be disposed on the peripheral wiring line 241a.

A first interlayer insulating film 263 may be disposed on the peripheral connection wiring 243. The first interlayer insulating film 263 may include an insulating material.

The data storage patterns DSP may be disposed on the first interlayer insulating film 263. The first interlayer insulating film 263 may be arranged between the data storage patterns DSP and the peripheral connection wiring 243.

The data storage patterns DSP may be electrically connected to the channel patterns AP. As illustrated in FIG. 2, the data storage patterns DSP may be arranged in a matrix form along a first direction DR1 and a second direction DR2.

Here, the first direction DR1 and the second direction DR2 may be perpendicular to the third direction DR3. The first direction DR1 may intersect the second direction DR2. For example, the third direction DR3 may be the thickness direction of the substrate 100. The first direction DR1 and the second direction DR2 may be parallel to the upper surface of the substrate 100.

For example, the data storage patterns DSP may be capacitors. The data storage patterns DSP may include capacitor dielectric films 253 disposed between storage electrodes 251 and plate electrodes 255. From a planar perspective, the storage electrodes 251 may have various shapes such as circular, elliptical, rectangular, square, diamond-shaped, or hexagonal. The storage electrodes 251 may penetrate a first etch stop film 247. The first etch stop film 247 may include an insulating material.

The storage electrodes 251 and the plate electrodes 255 may each include at least one of a conductive semiconductor material, a conductive metal nitride, a conductive metal silicon nitride, a metal carbonitride, a conductive metal silicide, a conductive metal oxide, or a metal. The capacitor dielectric films 253 may include at least one of a ferroelectric material, an antiferroelectric material, or a paraelectric material. For example, the capacitor dielectric films 253 may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, or a combination of a ferroelectric material, an antiferroelectric material, and a paraelectric material.

Alternatively, the data storage patterns DSP may be variable resistance patterns that switch between two resistance states based on electrical pulses applied to memory elements. For example, the data storage patterns DSP may include a phase-change material, a perovskite compound, a transition metal oxide, a magnetic material, a ferromagnetic material, or an antiferromagnetic material whose crystal state changes depending on the amount of current applied.

The contact patterns BC may be disposed on the data storage patterns DSP. The contact patterns BC may be disposed on the storage electrodes 251, respectively. The storage electrodes 251 may be in contact with the contact patterns BC. From a planar perspective, the contact patterns BC may have various shapes such as circular, elliptical, rectangular, square, diamond-shaped, or hexagonal.

A contact isolation insulating film 235 may be disposed on the first etch stop film 247. The contact isolation insulating film 235 may be disposed between the contact patterns BC. From a planar perspective, the contact patterns BC may be arranged in a matrix form along the first direction DR1 and the second direction DR2. The contact isolation insulating film 235 may include an insulating material.

The contact patterns BC may each include a first surface BC_S1 and a second surface BC_S2 opposite to each other in the third direction DR3. The first surfaces BC_S1 of the contact patterns BC may face the data storage patterns DSP. The data storage patterns DSP may be connected to the first surfaces BC_S1 of the contact patterns BC. The storage electrodes 251 may be in contact with the first surfaces BC_S1 of the contact patterns BC.

The contact isolation insulating film 235 may fill the spaces between the contact patterns BC. For example, the contact isolation insulating film 235 may entirely cover the sidewalls of the contact patterns BC.

The data storage patterns DSP may either completely or partially overlap the contact patterns BC along the third direction DR3. The data storage patterns DSP may be in contact with all or parts of the first surfaces BC_S1 of the contact patterns BC.

The contact patterns BC may include a conductive material. For example, the contact patterns BC may each include at least one of a doped polysilicon, a conductive metal nitride, a conductive metal silicon nitride, a metal carbonitride, a conductive metal silicide, a conductive metal oxide, a 2D material, a metal, or a metal alloy.

A protruding insulating pattern 175 may be disposed on the contact patterns BC and a contact isolation insulating film 235. A bitline sacrificial film 180 may be disposed on the protruding insulating pattern 175. The protruding insulating pattern 175 and the bitline sacrificial film 180 may be in contact with each other.

The protruding insulating pattern 175 and the bitline sacrificial film 180 may each include an insulating material. The protruding insulating pattern 175 and the bitline sacrificial film 180 may include different insulating materials. In the semiconductor memory device, the protruding insulating pattern 175 may include, but is not limited thereto, silicon nitride, and the bitline sacrificial film 180 may include, but is not limited thereto, silicon oxide.

The protruding insulating pattern 175 is illustrated as a single film, but is not limited thereto. In another example, the protruding insulating pattern 175 may also be formed as a multilayer film. For example, the protruding insulating pattern 175 may have a laminated insulating film structure in which silicon oxide, silicon nitride, and silicon oxide are stacked.

The protruding insulating pattern 175 may include a plurality of channel trenches CH_T. The channel trenches CH_T may each extend in the first direction DR1. Adjacent channel trenches CH_T may be spaced apart from each other in the second direction DR2.

The channel trenches CH_T may expose the contact patterns BC, respectively. The second surfaces BC_S2 of the contact patterns BC may be exposed by the channel trenches CH_T. For example, portions of the second surfaces BC_S2 of the contact patterns BC may be exposed by the channel trenches CH_T.

The channel patterns AP may be disposed on the data storage patterns DSP. The data storage patterns DSP may be disposed between the channel patterns AP and the substrate 100. The channel patterns AP may be disposed on the contact patterns BC. The channel patterns AP may be connected to the contact patterns BC, respectively. The channel patterns AP may be connected to the second surfaces BC_S2 of the contact patterns BC.

The channel patterns AP may be spaced apart from each other in the first direction DR1. The channel patterns AP may be spaced apart at regular intervals. The channel patterns AP may be disposed inside the channel trenches CH_T extending in the first direction DR1. Multiple channel patterns AP may be disposed inside a single channel trench CH_T.

Gate isolation patterns GSS, which will be described later, may be disposed between the channel patterns AP. That is, the channel patterns AP may be arranged to face each other with respect to gate isolation patterns 153, which will be described later. The channel patterns AP may have symmetrical shapes, but are not limited thereto. In another example, the channel patterns AP may have different shapes. The following description assumes that the channel patterns AP have the same shape, as illustrated.

A width K1 of the channel patterns AP in the second direction DR2 may be the same as a width K2 of bottom surfaces AP_BS of the channel patterns AP in the second direction DR2. In other words, the width of the channel patterns AP in the second direction DR2 may be uniform.

The channel patterns AP may each include an oxide semiconductor material. For example, the channel patterns AP may each include a metal oxide. In one example, the channel patterns AP may each include an amorphous metal oxide film. In another example, the channel patterns AP may each include a polycrystalline metal oxide film. In yet another example, the channel patterns AP may each include a combination of an amorphous metal oxide film and a polycrystalline metal oxide film. In still another example, the channel patterns AP may each include a c-axis aligned crystalline (CAAC) metal oxide film.

For example, the channel patterns AP may each include one of an indium oxide, a tin oxide, a zinc oxide, an In-Zn-based oxide, an Sn-Zn-based oxide, an Al-Zn-based oxide, a Zn-Mg-based oxide, an Sn-Mg-based oxide, an In-Mg-based oxide, an In-Ga-based oxide, an In-Ga-Zn-based oxide, an In-Al-Zn-based oxide, an In-Sn-Zn-based oxide, an Sn-Ga-Zn-based oxide, an Al-Ga-Zn-based oxide, an Sn-Al-Zn-based oxide, an In-Hf-Zn-based oxide, an In-La-Zn-based oxide, an In-Ce-Zn-based oxide, an In-Pr-Zn-based oxide, an In-Nd-Zn-based oxide, an In-Sm-Zn-based oxide, an In-Eu-Zn-based oxide, an In-Gd-Zn-based oxide, an In-Tb-Zn-based oxide, an In-Dy-Zn-based oxide, an In-Ho-Zn-based oxide, an In-Er-Zn-based oxide, an In-Tm-Zn-based oxide, an In-Yb-Zn-based oxide, an In-Lu-Zn-based oxide, an In-Sn-Ga-Zn-based oxide, an In-Hf-Ga-Zn-based oxide, an In-Al-Ga-Zn-based oxide, an In-Sn-Al-Zn-based oxide, an In-Sn-Hf-Zn-based oxide, or an In-Hf-Al-Zn-based oxide, but are not limited thereto.

Here, the term “In-Ga-Zn-based oxide” refers to an oxide having In, Ga, and Zn as its major components, and does not indicate the ratio of In, Ga, and Zn. That is, in the case of an In-Ga-Zn-based oxide, for example, the channel patterns AP may include indium gallium zinc oxide (IGZO, InₓGa_{y}Zn_{z}O). IGZO (In:Ga:Zn=1:1:1) that contains In, Ga, and Zn in equal proportions may be classified as an In-Ga-Zn-based oxide. A Ga-rich IGZO may have a higher Ga content and a lower In content compared to IGZO (In:Ga:Zn=1:1:1). A Ga-rich IGZO may also be classified as an In-Ga-Zn-based oxide. Additionally, an In-rich IGZO may have a higher indium content and a lower gallium content compared to IGZO (In:Ga:Zn=1:1:1). An In-rich IGZO may also be classified as an In-Ga-Zn-based oxide.

The above description has been provided taking IGZO as an example, but the present disclosure is not limited thereto. If the channel patterns AP include a ternary or higher metal oxide, the above description may still be applicable. Additionally, when the channel patterns AP include an In-Ga-Zn-based oxide, the channel patterns AP may further include a doped metal element in addition to In, Ga, and Zn.

First wordlines WL1 and second wordlines WL2 may be disposed between the gate isolation patterns GSS, which will be described later, and the channel patterns AP. The first wordlines WL1 and the second wordlines WL2 may be disposed inside the channel trenches CH_T.

The first wordlines WL1 and the second wordlines WL2 may each extend in the first direction DR1. The first wordlines WL1 and the second wordlines WL2 may be alternately arranged in the second direction DR2. The first wordline WL1 may be spaced apart from the second wordline WL2 in the second direction DR2. The first wordlines WL1 and the second wordlines WL2 may each be disposed between multiple channel patterns AP. The first wordlines WL1 and the second wordlines WL2 may each have a width in the second direction DR2.

The first wordlines WL1 and the second wordlines WL2 may each include first portions WLa and second portions WLb that are alternately arranged along the first direction DR1. The channel patterns AP may be disposed between adjacent second portions WLb of the first wordline WL1 in the first direction DR1. The channel patterns AP may also be disposed between adjacent second portions WLb of the second wordline WL2 in the first direction DR1.

The first wordlines WL1 and the second wordlines WL2 may include a conductive material. For example, the first wordlines WL1 and the second wordlines WL2 may include at least one of a doped polysilicon, a conductive metal nitride, a conductive metal silicon nitride, a metal carbonitride, a conductive metal silicide, a conductive metal oxide, a 2D material, a metal, or a metal alloy.

The wordlines (WL1 and WL2) may each include an upper surface WL_US and a lower surface opposite to each other in the third direction DR3. The lower surfaces of the wordlines (WL1 and WL2) may face the second surfaces BC_S2 of the contact patterns BC.

In FIG. 5, the upper surfaces WL_US of the wordlines (WL1 and WL2) may be planar. Contrary to what is illustrated, in one example, the upper surfaces WL_US of the wordlines (WL1 and WL2) may be convexly rounded. In another example, the upper surfaces WL_US of the wordlines (WL1 and WL2) may be concavely rounded.

Gate insulating films GOX may be disposed between the first wordlines WL1 and the channel patterns AP, between the second wordlines WL2 and the channel patterns AP, and between the gate isolation patterns GSS, which will be described later, and the contact patterns BC. The gate insulating films GOX may extend in the first direction DR1, parallel to the first wordlines WL1 and the second wordlines WL2.

From a cross-sectional perspective, the gate insulating films GOX disposed between the first wordlines WL1 and the channel patterns AP may be directly connected to the gate insulating films GOX disposed between the second wordlines WL2 and the channel patterns AP.

The gate insulating films GOX may each include a silicon oxide film, a silicon oxynitride film, a high-k dielectric insulating film having a greater dielectric constant than a silicon oxide film, or a combination thereof. For example, the gate insulating films GOX may include aluminum oxide, but are not limited thereto.

The gate isolation patterns GSS may be disposed between adjacent wordlines (WL1 and WL2) in the second direction DR2. The wordlines (WL1 and WL2) may be separated by the gate isolation patterns GSS. The gate isolation patterns GSS may extend in the first direction DR1 between the wordlines (WL1 and WL2).

The gate isolation patterns GSS may each include a horizontal portion and a protruding portion. The protruding portions of the gate isolation patterns GSS may protrude in the third direction DR3 from the horizontal portions of the gate isolation patterns GSS toward the peripheral gate structure PG. The protruding portions of the gate isolation patterns GSS may be disposed closer than the horizontal portions of the gate isolation patterns GSS to the peripheral gate structure PG. From a cross-sectional perspective, the gate isolation patterns GSS may each have a T-shaped structure.

The gate isolation patterns GSS may each include a gate isolation liner 151 and a gate isolation filling film 153. The gate isolation liners 151 of the gate isolation patterns GSS may extend along the upper surfaces of the wordlines (WL1 and WL2), the upper surfaces of the gate insulating films GOX, and the outer sidewalls of the wordlines (WL1 and WL2). The gate isolation filling films 153 of the gate isolation patterns GSS may be disposed on the gate isolation liners 151. The gate isolation liners 151 and the gate isolation filling films 153 may each include an insulating material. Contrary to what is illustrated, the gate isolation patterns GSS may be single films.

The bitlines BL may be disposed on the protruding insulating pattern 175. The bitlines BL may be connected to the metal structures 200. The bitlines BL may extend in the second direction DR2. Adjacent bitlines BL may be spaced apart in the first direction DR1.

In the semiconductor memory device, the data storage patterns DSP may be disposed between the peripheral gate structure PG and the bitlines BL.

The bitlines BL may each include an extension portion BLe and a protruding portion BLp. The extension portions BLe of the bitlines BL may extend in the second direction DR2. For example, the extension portions BLe of the bitlines BL may be formed through a subtractive etching process. The extension portions BLe of the bitlines BL may be disposed within a second interlayer insulating film 264. A third interlayer insulating film 265 may be disposed on the bitlines BL and the second interlayer insulating film 264. The second interlayer insulating film 264 and the third interlayer insulating film 265 may each include an insulating material.

The protruding portions BLp of the bitlines BL may protrude in the third direction DR3. The protruding portions BLp of the bitlines BL may protrude from the extension portions BLe of the bitlines BL toward the contact patterns BC. The protruding portions BLp of the bitlines BL may protrude from the extension portions BLe of the bitlines BL toward the data storage patterns DSP.

The protruding portions BLp of the bitlines BL may be electrically connected to the channel patterns AP. For example, the protruding portions BLp of the bitlines BL may be connected to the channel patterns AP through the metal structures 200 and the bitline contact liner 190, which will be described later. The protruding portions BLp of the bitlines BL may connect the channel patterns AP and the extension portions BLe of the bitlines BL.

The bitlines BL may include, for example, at least one of a doped semiconductor material, a conductive metal nitride, a conductive metal silicon nitride, a metal carbonitride, a conductive metal silicide, a conductive metal oxide, a 2D material, or a metal. The bitlines BL are illustrated as single films, but are not limited thereto.

The metal structures 200 may be disposed on the protruding insulating pattern 175. The metal structures 200 may be disposed between the protruding insulating pattern 175 and the bitlines BL. The metal structures 200 may electrically connect the bitlines BL and the channel patterns AP.

The metal structures 200 may each include an upper surface 200_US, a bottom surface 200_BS, outer sidewalls 200_OS, and inner sidewalls 200_IS. The upper surface 200_US and the bottom surface 200_BS may be connected by the outer sidewalls 200_OS and the inner sidewalls 200_IS. For example, the metal structures 200 may have a hollow cylindrical shape.

The metal structures 200 may surround the protruding portions BLp of the bitlines BL. The metal structures 200 may surround at least portions of sidewalls BLp_SW of the protruding portions BLp of the bitlines BL. For example, the inner sidewalls 200_IS of the metal structures 200 may face the protruding portions BLp of the bitlines BL. The inner sidewalls 200_IS of the metal structures 200 may face the sidewalls BLp_SW of the protruding portions BLp of the bitlines BL. The inner sidewalls 200_IS of the metal structures 200 may be in contact with the protruding portions BLp of the bitlines BL. The inner sidewalls 200_IS of the metal structures 200 may be in contact with the sidewalls BLp_SW of the protruding portions BLp of the bitlines BL.

The metal structures 200 may include a material that easily captures hydrogen (H). For example, the metal structures 200 may include titanium (Ti), but are not limited thereto. By capturing hydrogen generated during semiconductor processing, the metal structures 200 may reduce hydrogen diffusion into the channel patterns AP. Accordingly, the electrical characteristics of the semiconductor memory device may be improved.

A height H1 from the second surfaces BC_S2 of the contact patterns BC to the bottom surfaces 200_BS of the metal structures 200 may be smaller than a height H2 from the second surfaces BC_S2 of the contact patterns BC to the upper surfaces WL_US of the wordlines (WL1 and WL2). In other words, based on the second surfaces BC_S2 of the contact patterns BC, the upper surfaces WL_US of the wordlines (WL1 and WL2) may be disposed higher than the bottom surfaces 200_BS of the metal structures 200.

The bitline contact liner 190 may include first through fifth portions 190_P1 through 190_P5. The bitline contact liner 190 may be formed by continuously connecting the first through fifth portions 190_P1 through 190_P5. The bitline contact liner 190 may electrically connect the bitlines BL and the channel patterns AP.

The bitline contact liner 190 may cover the upper surfaces 200_US and bottom surfaces 200_BS of the metal structures 200. The bitline contact liner 190 may extend along the upper surfaces 200_US, outer sidewalls 200_OS, and bottom surfaces 200_BS of the metal structures 200. At least portions of the bitline contact liner 190 may be in contact with the channel patterns AP. The bitline contact liner 190 may not be in contact with the inner sidewalls 200_IS of the metal structures 200.

The first portion 190_P1 of the bitline contact liner 190 may be disposed between the extension portions BLe of the bitlines BL and the gate isolation liners 151. The first portion 190_P1 of the bitline contact liner 190 may be formed along at least portions of the gate isolation liners 151.

The second portion 190_P2 of the bitline contact liner 190 may be formed along at least portions of the sidewalls BLp_SW of the protruding portions BLp of the bitlines BL. The second portion 190_P2 of the bitline contact liner 190 may be disposed between the sidewalls BLp_SW of the protruding portions BLp of the bitlines BL and the gate isolation liners 151, and between the sidewalls BLp_SW of the protruding portions BLp of the bitlines BL and the gate insulating films GOX.

The third portion 190_P3 of the bitline contact liner 190 may be disposed between the gate insulating films GOX and the upper surfaces 200_US of the metal structures 200. The fourth portion 190_P4 of the bitline contact liner 190 may be disposed between the metal structures 200 and the channel patterns AP. The fifth portion 190_P5 of the bitline contact liner 190 may be disposed between the metal structures 200 and the protruding insulating pattern 175, and between the bottom surfaces BLp_BS of the protruding portions BLp of the bitlines BL and the protruding insulating pattern 175.

A width W1 of the second portion 190_P2 of the bitline contact liner 190 in the second direction DR2 may be smaller than a width W2 of the protruding portions BLp of the bitlines BL in the second direction DR2. The bitline contact liner 190 may include, for example, molybdenum (Mo), but is not limited thereto.

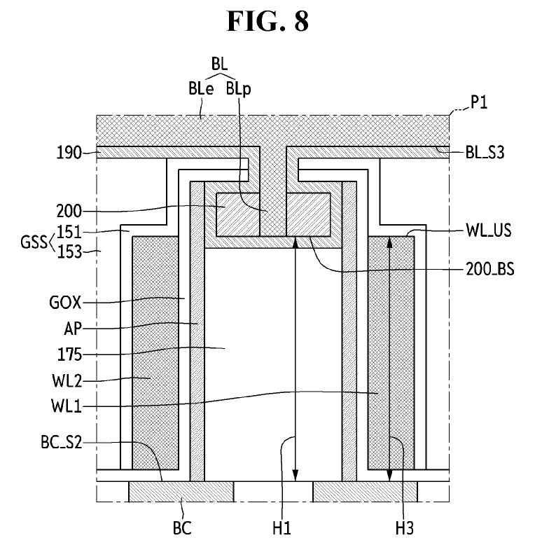

FIG. 8 is an enlarged view of portion P1 (in FIG. 3) of an example of a semiconductor memory device. For convenience, the implementations of FIG. 8 will hereinafter be described, focusing mainly on the differences from the implementations of FIGS. 1 through 7.

Referring to FIG. 8, in the semiconductor memory device, a height H1 from a second surface BC_S2 of a contact pattern BC to a bottom surface 200_BS of a metal structure 200 may be the same as a height H3 from the second surface BC_S2 of the contact pattern BC to upper surfaces WL_US of wordlines (WL1 and WL2). In other words, based on the second surface BC_S2 of the contact pattern BC, the upper surfaces WL_US of wordlines (WL1 and WL2) may be disposed on the same plane as the bottom surface 200_BS of the metal structure 200.

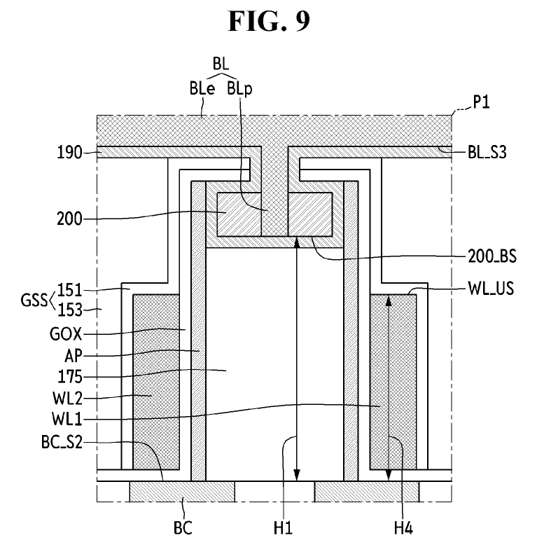

FIG. 9 is an enlarged view of portion P1 (in FIG. 3) of an example of a semiconductor memory device. For convenience, the implementations of FIG. 9 will hereinafter be described, focusing mainly on the differences from the implementations of FIGS. 1 through 8.

Referring to FIG. 9, in the semiconductor memory device, a height H1 from a second surface BC_S2 of a contact pattern BC to a bottom surface 200_BS of a metal structure 200 may be greater than a height H4 from the second surface BC_S2 of the contact pattern BC to upper surfaces WL_US of wordlines (WL1 and WL2). In other words, based on the second surface BC_S2 of the contact pattern BC, the upper surfaces WL_US of the wordlines (WL1 and WL2) may be disposed lower than the bottom surface 200_BS of the metal structure 200.

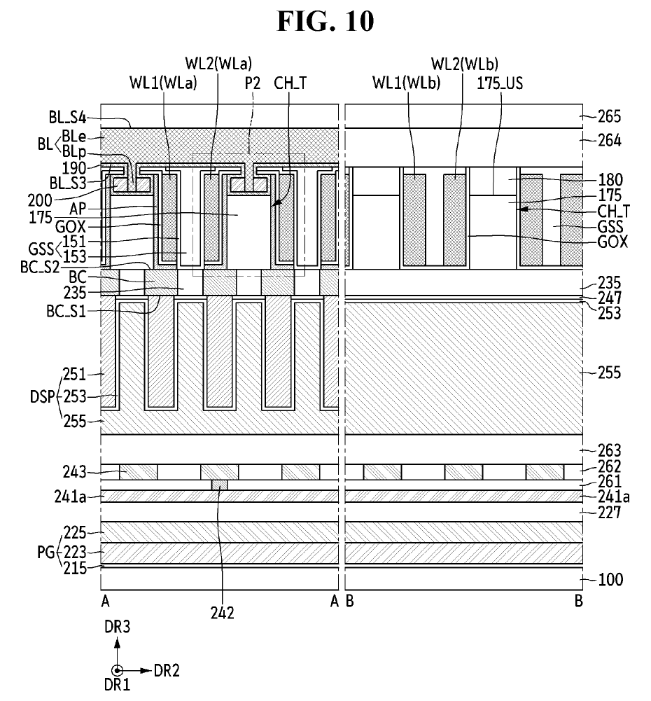

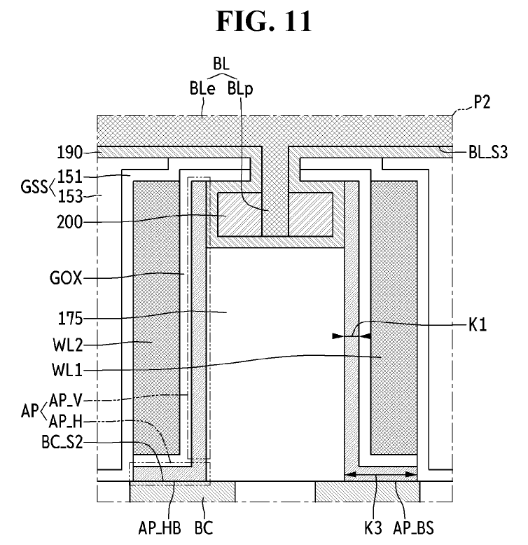

FIG. 10 is a cross-sectional view, taken along lines A-A and B-B of FIG. 2, of an example of a semiconductor memory device. FIG. 11 is an example enlarged view of portion P2 in FIG. 10. For convenience, the implementations of FIGS. 10 and 11 will hereinafter be described, focusing mainly on the differences from the implementations of FIGS. 1 through 7.

Referring to FIGS. 10 and 11, in the semiconductor memory device, channel patterns AP may each include a horizontal portion AP_H and a vertical portion AP_V that are connected to each other. For example, the channel patterns AP may each have an L-shaped structure where the horizontal portion AP_H and the vertical portion AP_V are connected. The horizontal portions AP_H of the channel patterns AP may be in contact with contact patterns BC. For example, bottom surfaces AP_HB of the horizontal portions AP_H of the channel patterns AP may be in contact with the contact patterns BC. The vertical portions AP_V of the channel patterns AP may extend in a third direction DR3 from the horizontal portions AP_H of the channel patterns AP. A width K1 of the channel patterns AP in a second direction DR2 may be smaller than a width K3 of bottom surfaces AP_BS of the channel patterns AP in the second direction DR2.

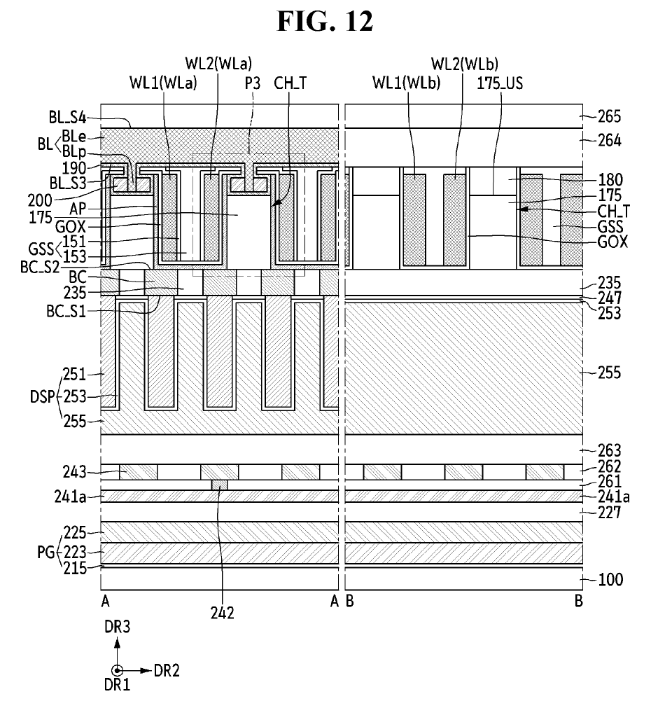

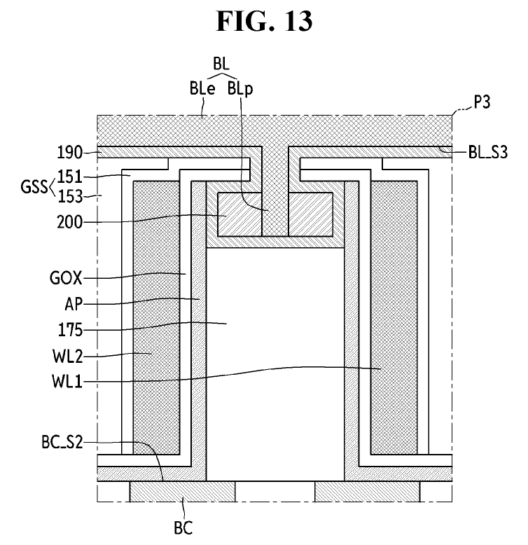

FIG. 12 is a cross-sectional view, taken along lines A-A and B-B of FIG. 2, of an example of a semiconductor memory device. FIG. 13 is an example enlarged view of portion P2 in FIG. 12. For convenience, the implementations of FIGS. 12 and 13 will hereinafter be described, focusing mainly on the differences from the implementations of FIGS. 1 through 7.

Referring to FIGS. 12 and 13, in the semiconductor memory device, channel patterns AP may be disposed along second surfaces BC_S2 of contact patterns BC and the upper surface of a contact isolation insulating film 235. In other words, the channel patterns AP may cover both the second surfaces BC_S2 of the contact patterns BC and the upper surface of the contact isolation insulating film 235.

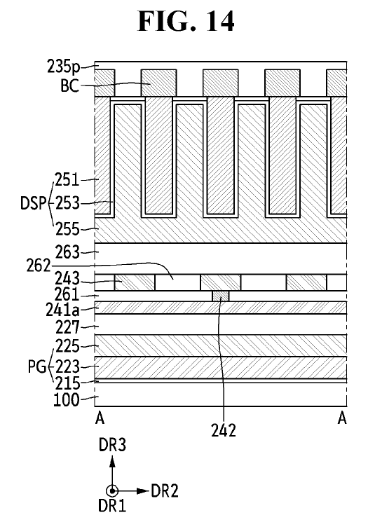

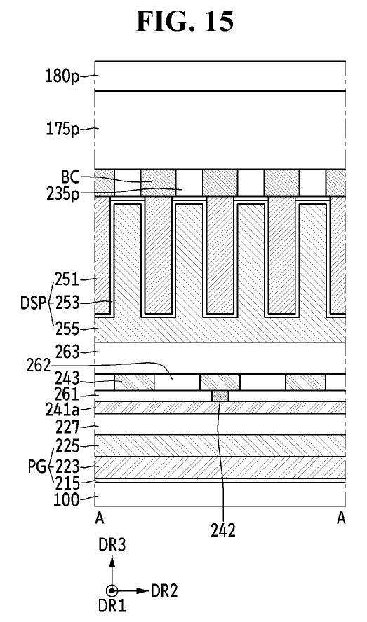

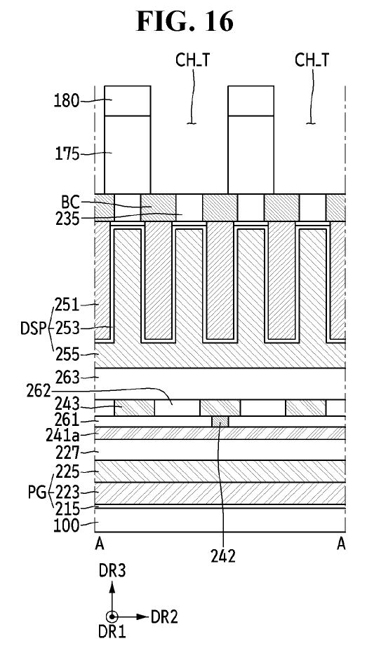

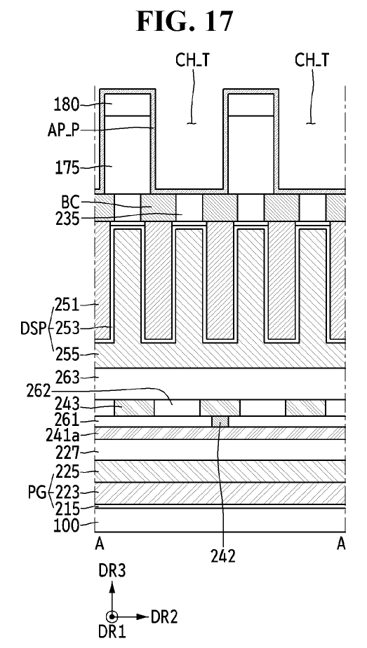

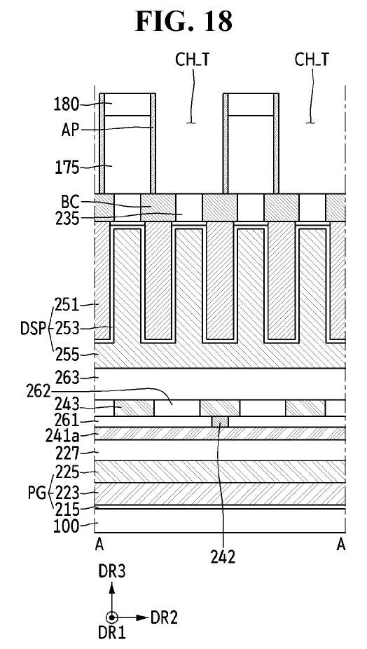

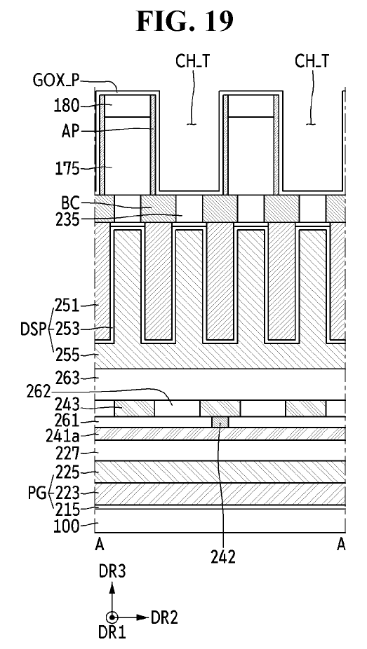

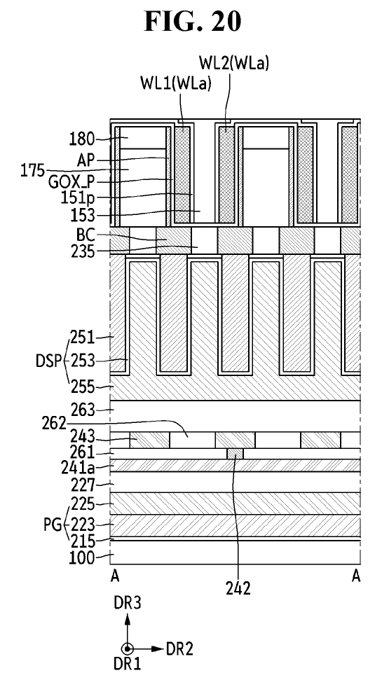

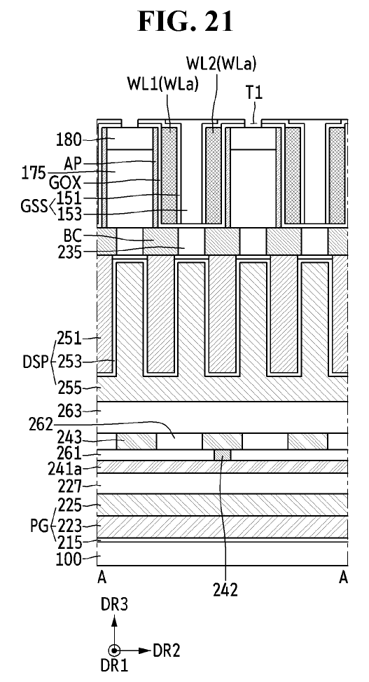

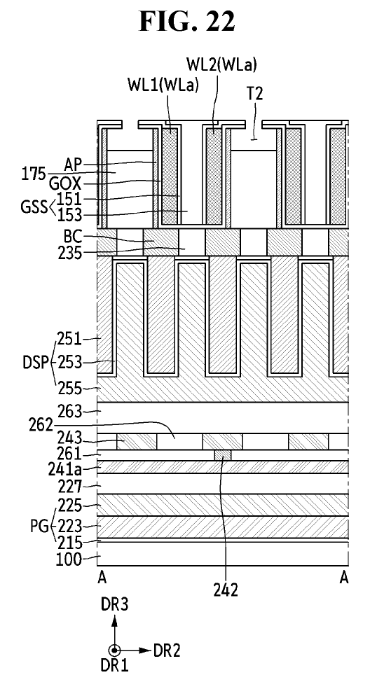

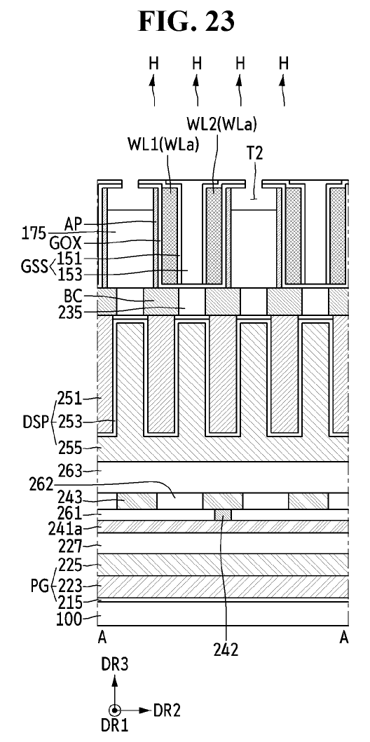

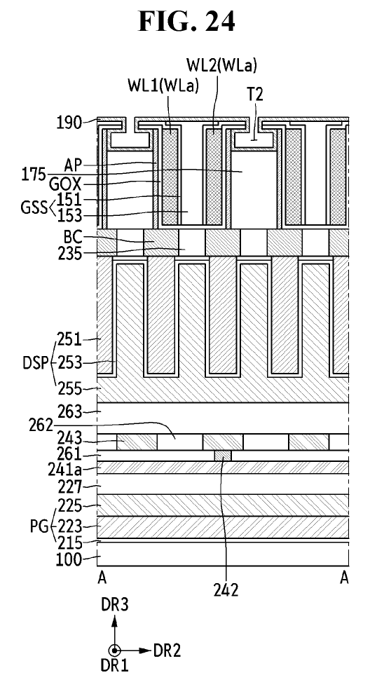

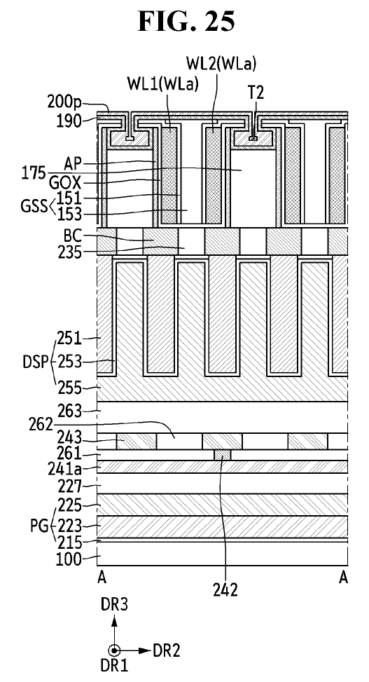

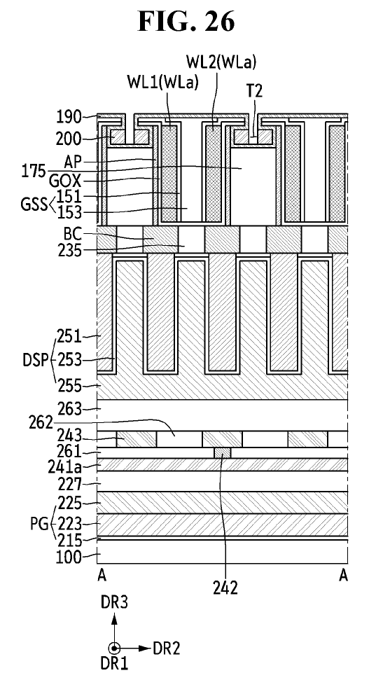

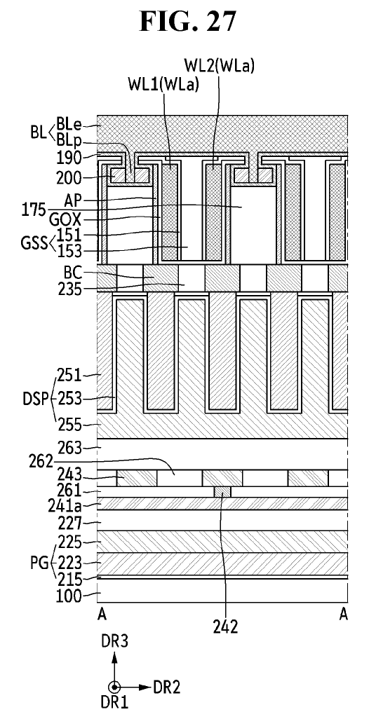

FIGS. 14,15,16,17,18,19,20,21,22,23,24,25,26, and 27 illustrate intermediate steps of an example of a method of fabricating a semiconductor memory device.

Referring to FIG. 14, contact patterns BC and a pre-contact isolation insulating film 235p may be formed on a sub-substrate. The contact patterns BC may be formed inside the pre-contact isolation insulating film 235p. The contact patterns BC may be disposed on the sub-substrate.

Data storage patterns DSP may be formed on the contact patterns BC and the pre-contact isolation insulating film 235p.

Thereafter, the sub-substrate, on which the data storage patterns DSP and the contact patterns BC are formed, may be bonded to a substrate 100. The data storage patterns DSP and the substrate 100 may be bonded by a first interlayer insulating film 263.

Contrary to what is illustrated, before the bonding of the sub-substrate to the substrate 100, a peripheral gate structure (“PG” in FIG. 3) may be formed on the substrate 100. In this case, the sub-substrate, on which the data storage patterns DSP and the contact patterns BC are formed, may be bonded to the substrate 100 on which the peripheral gate structure PG is formed.

After the bonding of the sub-substrate and the substrate 100, the sub-substrate may be removed.

Referring to FIG. 15, portions of the pre-contact isolation insulating film 235p in FIG. 14 may be removed, thereby forming a contact isolation insulating film 235. Thereafter, a pre-protruding insulating pattern 175p and a pre-bitline sacrificial film 180p may be sequentially formed on the contact patterns BC and the contact isolation insulating film 235.

Referring to FIG. 16, channel trenches CH_T may be formed in the pre-protruding insulating pattern 175p and a pre-bitline sacrificial film 180p. The channel trenches CH_T may extend in a first direction DR1. As a result, a protruding insulating pattern 175 and a bitline sacrificial film 180, including the channel trenches CH_T, may be formed on the contact patterns BC and the contact isolation insulating film 235.

Referring to FIG. 17, a pre-channel pattern AP_P may be formed along the upper surface of the bitline sacrificial film 180, and along the sidewalls and bottom surfaces of the channel trenches CH_T. Thereafter, referring to FIG. 18, portions of the pre-channel pattern AP_P in FIG. 17 may be removed, thereby forming channel patterns AP. Specifically, portions of the pre-channel pattern AP_P on the upper surfaces of the contact pattern BC, the contact isolation insulating film 235, and the bitline sacrificial film 180 may be removed.

Referring to FIG. 19, a pre-gate insulating film GOX_P may be formed along the upper surface of the bitline sacrificial film 180, and along the sidewalls and bottom surfaces of the channel trenches CH_T.

Referring to FIG. 20, first wordlines WL1 and second wordlines WL2 may be formed on the pre-gate insulating film GOX_P. The first wordlines WL1 and the second wordlines WL1 and WL2 may be disposed inside the channel trenches CH_T in FIG. 19. Thereafter, gate isolation patterns GSS may be formed on the first wordlines WL1 and the second wordlines WL1 and WL2. The gate isolation patterns GSS may fill the channel trenches CH_T. Portions of the gate isolation patterns GSS may be disposed on the upper surface of the protruding insulating pattern 175. Then, portions of the gate isolation patterns GSS may be removed to expose the upper surfaces of gate isolation patterns 153.

Thereafter, referring to FIG. 21, portions of the pre-gate insulating film GOX_P and the pre-gate isolation liner 151p in FIG. 20 may be removed, thereby forming gate insulating films GOX and gate isolation liners 151. As portions of the pre-gate insulating film GOX_P and the pre-gate isolation liner 151p are removed, first trenches T1 may be formed. As portions of the pre-gate insulating film GOX_P are removed, the upper surface of the bitline sacrificial film 180 may be exposed.

Referring to FIG. 22, the bitline sacrificial film 180 in FIG. 21 may be removed, thereby forming second trenches T2. For example, the bitline sacrificial film 180 may be removed through a dry etching process, but is not limited thereto. In another example, the bitline sacrificial film 180 may be removed through a wet etching process. Thereafter, referring to FIG. 23, an annealing process may be performed to remove hydrogen (H).

Referring to FIG. 24, a bitline contact liner 190 may be formed along the profile of the sidewalls of the second trenches T2 and the exposed upper surfaces of the gate isolation patterns GSS. The bitline contact liner 190 may be formed, for example, through an atomic layer deposition (ALD) process.

Referring to FIG. 25, a pre-metal structure 200p may be formed along the profile of the bitline contact liner 190. Specifically, the pre-metal structure 200p may be formed inside the second trenches T2 and on the upper surface of the bitline contact liner 190.

Referring to FIG. 26, portions of the pre-metal structure 200p in FIG. 25 may be removed, thereby forming metal structures 200. For example, the portions of the pre-metal structure 200p outside the second trenches T2 may be removed.

Thereafter, referring to FIG. 27, protruding portions BLp of bitlines BL may be formed inside the second trenches T2 in FIG. 26, and then, extension portions BLe of the bitlines BL may be formed on the upper surface of the bitline contact liner 190. The protruding portions BLp and the extension portions BLe of the bitlines BL may be formed in a single process, but are not limited thereto. In another example, the protruding portions BLp of the bitlines BL may be formed first, and then, the extension portions BLe of the bitlines BL may be formed.

Thereafter, referring again to FIG. 3, a third interlayer insulating film 265 may be formed on fourth surfaces BL_S4 of the bitlines BL. In other words, the third interlayer insulating film 265 may cover the fourth surfaces BL_S4 of the bitlines BL.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

In concluding the detailed description, those skilled in the art will appreciate that many variations and modifications may be made to the implementations without substantially departing from the principles of the present disclosure. Therefore, the disclosed implementations of the disclosure are used in a generic and descriptive sense only and not for purposes of limitation.

What is claimed is:

1. A semiconductor memory device comprising:
a contact pattern including a first surface and a second surface, the first surface and the second surface being opposite to each other in a first direction;
a data storage pattern connected with the first surface of the contact pattern;
a channel pattern connected with the second surface of the contact pattern;
a bitline disposed on the channel pattern, connected with the channel pattern, and including an extension portion and a protruding portion, wherein the extension portion of the bitline extends in a second direction and includes a third surface and a fourth surface, the third surface and the fourth surface are opposite to each other in the first direction, and the protruding portion of the bitline protrudes from the third surface of the extension portion of the bitline toward the contact pattern;
a metal structure at least partially surrounding a plurality of sidewalls of the protruding portion of the bitline; and
a wordline disposed on the channel pattern and extending in a third direction.

2. The semiconductor memory device of claim 1, comprising:
a bitline contact liner disposed between the channel pattern and the metal structure,
wherein the bitline contact liner includes a first portion, a second portion, and a third portion, the first portion extending along the third surface of the extension portion of the bitline and the plurality of sidewalls of the protruding portion of the bitline, the second portion extending along a boundary between the channel pattern and the metal structure, and the third portion extending along a bottom surface of the protruding portion of the bitline.

3. The semiconductor memory device of claim 2, wherein the bitline contact liner covers an upper surface of the metal structure and a bottom surface of the metal structure.

4. The semiconductor memory device of claim 1, wherein
the metal structure includes an upper surface, a bottom surface, a plurality of inner sidewalls, and a plurality of outer sidewalls, the upper surface and the bottom surface being opposite to each other in the first direction, and the plurality of inner sidewalls and the plurality of outer sidewalls connecting the upper surface and the bottom surface of the metal structure, and
the plurality of inner sidewalls of the metal structure face the protruding portion of the bitline.

5. The semiconductor memory device of claim 4, comprising:
a bitline contact liner disposed between the channel pattern and the metal structure,
wherein the bitline contact liner extends along the upper surface, the plurality of outer sidewalls, and the bottom surface of the metal structure.

6. The semiconductor memory device of claim 4, comprising:
a bitline contact liner disposed between the channel pattern and the metal structure,
wherein the bitline contact liner contacts the channel pattern.

7. The semiconductor memory device of claim 1, wherein a height from the second surface of the contact pattern to a bottom surface of the metal structure is smaller than a height from the second surface of the contact pattern to an upper surface of the wordline.

8. The semiconductor memory device of claim 1, wherein the metal structure includes titanium.

9. The semiconductor memory device of claim 1, comprising:
a bitline contact liner disposed between the channel pattern and the metal structure,
wherein the bitline contact liner includes molybdenum.

10. The semiconductor memory device of claim 1, comprising:
a gate insulating film disposed between the channel pattern and the wordline.

11. The semiconductor memory device of claim 1, comprising:
a protruding insulating pattern disposed between the contact pattern and the metal structure, the protruding insulating pattern including a channel trench,
wherein the channel pattern and the wordline are disposed inside the channel trench.

12. The semiconductor memory device of claim 1, comprising:
a bitline contact liner disposed between the channel pattern and the metal structure, wherein the bitline contact liner includes a first portion, a second portion, and a third portion, the first portion extending along the third surface of the extension portion of the bitline and the plurality of sidewalls of the protruding portion of the bitline, the second portion extending along a boundary between the channel pattern and the metal structure, and the third portion extending along a bottom surface of the protruding portion of the bitline,
wherein a width of the second portion of the bitline contact liner in the second direction is smaller than a width of the protruding portion of the bitline in the second direction.

13. A semiconductor memory device comprising:
a contact pattern including a first surface and a second surface, the first surface and the second surface being opposite to each other in a first direction;
a data storage pattern connected with the first surface of the contact pattern;
a channel pattern connected with the second surface of the contact pattern;
a bitline disposed on the channel pattern and connected with the channel pattern;
a metal structure disposed between the bitline and the channel pattern, the metal structure including an upper surface and a bottom surface, the upper surface and the bottom surface being opposite to each other in the first direction, and a plurality of inner sidewalls and a plurality of outer sidewalls connecting the upper surface and the bottom surface; and
a wordline disposed on the channel pattern and extending in a second direction,
wherein the plurality of inner sidewalls of the metal structure contact the bitline.

14. The semiconductor memory device of claim 13, wherein
the bitline includes an extension portion and a protruding portion,
the extension portion of the bitline extends in the second direction and includes a third surface and a fourth surface, the third surface and the fourth surface being opposite to each other in the first direction, and
the protruding portion of the bitline protrudes from the third surface of the extension portion of the bitline toward the contact pattern.

15. The semiconductor memory device of claim 13, comprising:
a bitline contact liner disposed between the channel pattern and the metal structure,
wherein the bitline contact liner extends along the upper surface, the plurality of outer sidewalls, and the bottom surface of the metal structure.

16. The semiconductor memory device of claim 13, wherein a height from the second surface of the contact pattern to the bottom surface of the metal structure is smaller than a height from the second surface of the contact pattern to an upper surface of the wordline.

17. The semiconductor memory device of claim 13, comprising:
a gate insulating film disposed between the channel pattern and the wordline,
wherein in a cross-sectional view, the gate insulating film is separated from the second surface of the contact pattern.

18. The semiconductor memory device of claim 13, wherein the metal structure includes titanium.

19. A semiconductor memory device comprising:
a peripheral gate structure disposed on a substrate;
a contact pattern disposed on the peripheral gate structure and including a first surface and a second surface, the first surface and the second surface being opposite to each other in a first direction;
a data storage pattern disposed between the peripheral gate structure and the contact pattern, the data storage pattern being connected with the first surface of the contact pattern;
a channel pattern connected with the second surface of the contact pattern;
a bitline disposed on the channel pattern, connected with the channel pattern, and including an extension portion and a protruding portion, wherein the extension portion of the bitline extends in a second direction and includes a third surface and a fourth surface, the third surface and the fourth surface are opposite to each other in the first direction, and the protruding portion of the bitline protrudes from the third surface of the extension portion of the bitline toward the contact pattern;
a metal structure at least partially surrounding a plurality of sidewalls of the protruding portion of the bitline;
a wordline disposed on the channel pattern and extending in a third direction; and
a bitline contact liner disposed between the channel pattern and the metal structure,
wherein the bitline contact liner includes a first portion, a second portion, and a third portion, the first portion extending along the third surface of the extension portion of the bitline and the plurality of sidewalls of the protruding portion of the bitline, the second portion extending along a boundary between the channel pattern and the metal structure, and the third portion extending along a bottom surface of the protruding portion of the bitline.

20. The semiconductor memory device of claim 19, wherein
the metal structure includes titanium, and
the bitline contact liner includes molybdenum.
